(19) United States
(12) Patent Application Publication
(10) Pub. No.: US 2010/0098964 A1
(43) Pub. Date: Apr. 22, 2010

(54) METHOD FOR THE PRODUCTION OF A COATING

(76) Inventor: Guenter Ruebig, Wels (AT)

Correspondence Address: COLLARD & ROE, P.C., 1077 NORTHERN BOULEVARD, ROSLYN, NY, 11576, US

(21) Appl. No.: 12/449,117

(22) PCT Filed: Feb. 29, 2008
(86) PCT No.: PCT/AT2008/000068

§ 371 Date: Aug. 18, 2009

(30) Foreign Application Priority Data
Mar. 1, 2007 (AT) A 318/2007

(51) Int. Cl. C23C 8/20; B05D 3/10; C23C 8/44; C23C 8/24; C23C 16/02; B32B 15/04

(52) U.S. Cl. 428/547; 427/299; 427/535; 428/469; 428/156; 428/141

(57) ABSTRACT

The invention describes a process for the production of a coating (6) on the basis of at least one material selected from a group comprising silicon, germanium, and the oxides SiOₓ or GeOₓ of these elements, whereby these are doped where applicable and produced specifically amorphised, on at least a subsection of a surface (3) of a metallic substrate (2), whereby the concentration of nitrate is increased in the substrate (2) where applicable prior to precipitation of the coating (6) at least in the area of the subsection. This subsection is subjected to oxidation prior to precipitation of the coating (6).

This document will contain instructions on the manufacturing of coating with at least one of the working materials chosen from a group that contains silicon or germanium, as well as the oxide of each chemical element that each is to be doped with. In particular, where chemical elements are amorphously manufactured, or where the concentration of substrate in a specific area of a metallic substrate surface, as the case may be, is increased prior to precipitation of the coating, at least in that specific area, a device can be manufactured following the instructions and it includes a metallic substrate that features in a specific area of the coatings. Use of the device will also be shown.

Metallic surfaces must yield differing energy spectra. In order to fulfil this, it is usual on the one hand to alter the coating that is near to the surface, for instance through nitrogen hardening so as to increase abrasion resistance. On the other hand, it is also possible to fix or attach coatings so that not only is protection of the underlying metallic surface achieved but also the surface coating with respective necessary properties is also made available. Likewise, from a technical point of view, we recognise that there is general improvement of tribology¹ of metallic surfaces through the use of carbonic surfaces. Amongst a large area of similar types of coating materials, hydrogenous carbonic coatings are mentioned in particular. Due in part to the diamond like coating properties, these coating are often referred to as DLC (diamond like carbon) coatings. 1 Interacting surfaces in relative motion.

For further improvement of these coating, variations of these will be described. Likewise, it is possible to increase electrical conductivity by applying metal to the coatings. Through application of non-metallic elements such as fluorine, silicon, oxygen, nitrate or boron, it is possible to alter surface energies of the coatings that affect wetting characteristics. The manufacture of such coatings generally takes place through plasma enhanced chemical vapour deposition (PECVD).

Sputter operations have already been discussed in WO 0303/064720 A, for example where the target was established as a carbonic target, a graphite target more precisely, and a negative DC voltage was pre-tensioned.

As expected from the chemical similarities between silicon and carbon, state of the art DLC-coatings from a silicon base are described in literature: Increased adhesion of diamond-like carbon-Si coatings and its tribological properties; H. Mori, H. Tachikawa; Surface and Coatings Technology 149, 2002, 225-230 and Continuously deposited duplex coatings consisting of plasma nitriding and a-C:H:Si deposition; T. Michler, N. Grischke, H. Bewilogua, A. Hieke; Surface and Coatings Technology 111, 1999, 41-45.

From the publication Investigation of DLC-Si coatings in large-scale production using DC-PACVD equipment; K. Nakanishi, et al.; Surface and Coatings Technology 200, 2006, 4277-4281” it becomes know that in order to improve the adhesive strength of the DLC coating, the substrate must be pretreated with nitriding and subsequently with ionic sputtering.

The task of this paper is make a metallic work piece with improved surface qualities available to us.

This task will be independently solved through the examination of given instructions for coating manufacturing, that is for the specific area of the surface to the coating of metallic substrates, prior to precipitation itself, oxidation will be carried out. The same will apply to equipment made from metallic substrate that is in surface areas, meaning those parts the prepared specific area that are pretreated for coating. Through oxidative pretreatment and the oxide coating that results from it, increased adhesive strength of the metallic substrate, as the case may be doted substrate with silicon or germanium-based, for example, will be achieved. Below, in terms of the experiment, the particular oxide coatings SiO₂ and GeO₂ will be understood drawing on the teachings of Van-der-Waals that differentiate between oxygen, silicon and germanium volumes in the surface area. Furthermore, with this coating composition, an improvement in adhesive behaviour as well as emergency operation characteristics when the work piece is under tribological strain is achieved. This occurs through the altering of the surface topography of the work piece. Thus, the surface of certain tips and toothwork that are a result of the pretreatment process, particularly from the oxidation process originating from sealing, can be freed. An advantage of this is that the surface finish can be left untouched by the sealing process, or as the case may be, with appropriate implementation methods, can lead to the surface finish reducing. In this case, the surface energy is also reduced so that the adhesive capacity to other work pieces e.g. wood, plastic and metal is reduced during working of the same materials. Therefore, this coating system can be employed with silicon and germanium-based coatings as well as adhesive agents for further implementation of coatings on the metallic substrate. This applies also to further plasma techniques, as mentioned above, will metals such as titanium and silicon, as the case may be that are doped, hydrogenous carbonic coatings (DLC coatings). As an additional effect that go hand in hand with the principles of the invention of coating systems, another advantage arises and it is that the parts have a smooth, black to deep black surface without needing any further finishing treatment, similar to black-oxide finished surfaces. They therefore have a particular optical effect that leads to positive results when it comes to the sale capacity of the respective parts.

In order to improve penetration and to increase abrasion resistance, hardness as well as improve resistance against corrosion of the substrate, the whole coating system as opposed to individual word pieces, which merely possess silicon-based coatings, it is advantageous that the nitriding is carried out after substrate oxidisation. This is to be carried out in conjunction with the coating, as it works as a surface sealant through oxidative pretreatment of the work piece as a consequence of covering surface defects in the oxide coating. For instance, an iron oxide coating such as Fe₃O₄, in our experience can be treated using mass production methods. Such surface imperfections develop as porosity in the surface of the work material in which corrosive attack can take place.

It is preferred that increase in nitrate concentration be carried out on surface areas of the substrate through the use of nitrogen hardening and carbon nitrogen hardening in plasmas respectively, so that the surface coating is kept with a very high degree of consistency of characteristics. Moreover, this method is more cost-effective and environmentally friendly, especially if Air,N₂ is used.

Oxidisation and water vapour also increase the environmentally friendly aspect of the methods, whereby additional impurities can be avoided resulting from the use of atmospheric oxygen, for example.

Through additional doping of the silicon and germanium-based coating that is on a particular area of the coating thickness with carbon and/or nitrate can further improve the wear resistance and the hardness of this coating. Following from this, friction can be brought down and resistance to heat can be increased. Furthermore, surface energy as well as wetting characteristics, which means stickiness can be lowered even further.

The expression ‘at least over a particular part of the coating thickness’ is to be understood to refer to the coating system, from a combination of SiO₂, GeO₂ and those contained within —Si(Ge)—O—C, Si(Ge)—O—N and/or Si(Ge)—O—C—N coating. Si—O—C/N and Ge—O—C/N respectively are not necessary meant stoichiometrically here. The manufacturing of these can follow on from gas composition and a variation of this composition due to precipitation.

It is to be seen as advantageous if the carbon concentration in silicon and germanium-based coating is regulated to a particular value, meaning that it is selected from a range with the lowest value at 1 Atom Percent and a highest value at 100 Atom Percent. Preferably, the carbon concentration will be set at a value that is selected from a range with the lowest value at 1 Atom Percent and the highest value at 25 Atom Percent, and selected from a range with the lowest value at 5 Atom Percent and the highest value at 15 Atom Percent respectively.

The indication of 100 Atom Percent should be understood as being carried out with a change of the coating system so that not more silicon or germanium or oxide from either constitute the main part of the coating. In fact, they should constitute a minor component when it comes to the coating cross section for the process to be carried out and refined with virtually pure DLC coating made from carbon on the surface. This alteration can be carried out, as will be later documented, in the form of a gradient or in stages so that a ‘multi-layer’ structure emerges, with varying composition of the coatings and where the concentration in silicon or germanium and concentration in carbon and/or nitrate increases. By way of example, it is therefore a graduated method for a ‘pure’ oxide coating that is made possible for the scope of the experiment for SiO₂ or GeO₂, for example, through an increase in the percentage of carbon and a decrease in the percentage of oxygen—a change to silicon or germanium DLC coating, in each case respectively.

The nitrate content in the silicon and germanium based coating, respectively, can be regulated to a selected value within a range with the lowest value at 1 Atom Percent, notably 2 Atom Percent, notably 3 Atom Percent by preference, with a highest value at 60 Atom Percent, notably 10 Atom Percent, notably 5 Atom Percent by preference. With regard to the 60 Atom Percent rate, it will be referred to the aforementioned model of high percentages in carbon.

In order to further improve these properties, the surface hardness and wear resistance in particular, as well as the adhesive force of silicon and germanium or silicon dioxide and germanium dioxide based coating on the oxide coating of the substrate, it would be an advantage for the carbon and nitrate doping for this coating to be regulated. It is also advantageous for the carbon and/or nitrate content resulting from it to increase with the substrate that is near to the surface coating in the direction of the external surface of the coating and thus the very coating itself that is anticipated. The concentration gradient can be regulated through a linear increase or non-linear increase, for instance with exponential progression. Here, it is possible that the carbon concentration reduces from 1 Atom Percent up to a value of 100 Atom Percent. In the same way, it is possible for the nitrate content to increase from a value of 1 Atom Percent to a value of 10 Atom Percent.

It is here that we must mention that although the concentration increase in nitrate and/or carbon is the preferred variable, it is also possible in the realms of the experiment for the concentration gradient of carbon and nitrate to decrease, for the carbon concentration gradient to increase and nitrate concentration gradient to decrease, and vice versa. Corresponding alteration to characteristics is a possibility here, in particular of those properties that are mentioned above, with respect to the different purposes of use for the present invention.

Furthermore, it is to be mentioned here that the percentage specifications on the amount of silicon and germanium dioxide, as well as silicon and germanium oxide with doping element(s) are given here.

As a variant here, the total concentration of doping substance, as well as doping elements, carbon and nitrate in particular are restricted to a maximal value—selected from a range with the lowest value at 5 Atom Percent, the highest value at 60 Atom Percent, and respectively selected from a range with the lowest value at 10 Atom Percent, the highest at 30 Atom Percent, for silicon and germanium, as well as silicon and germanium oxide, and silicon and germanium content with doping elements.

Separation of silicon or germanium-based coating is preferred using a pulsed DC voltage. There may be overheating of the work piece and the device, which should be avoided, where which the work piece comes into contact with energy for the duration of the pulses, in this case the or the duration of the pulse intervals will be varied. Preferably, a pulse will be selected with an amplitude, selected from a range with a lower limit of 300 V and an upper limit of 1500 V, a pulse duration with a lower limit of 0.1 micro-seconds and an upper limit of 2000 micro-seconds, or one with a lower pulse interval lower of 0.1 micro-seconds and an upper limit of 2000 μs. Here, the voltage pulses, both at least almost rectangular or with a rising edge and/or rising edge or of hybrid form may be used. The voltage pulse can have both a positive and a negative amplitude.

In the realms of this experiment it is also possible for the separation to be carried out via an alternating voltage, notably dipolar voltage, dipolar pulses or with high frequency sources.

Preference will also be placed on plasma nitriding or plasma carbonitriding with a pulsed DC voltage and thus also overheating of the work piece or the device during plasma treatment, which will thus avoid temperature control of the experiment. The corresponding values for the voltage amplitude or the duration of the applied pulses can also consist of above-mentioned selected ranges.

The coating thickness of silicon, which as the case may be, will be doped or of the silicon oxide or germanium oxide coating is preferably selected at a value with a lower limit of 1 micron and an upper limit of 25 microns. Below 1 micron, the safety involved in achieving the above properties for the coating can no longer be guaranteed to be consistent. For over 25 microns, however, no further improvements of the properties can be observed. It was however observed that at very high coating thicknesses, starting from approximately 50 microns, partial flaking of the coating occurs.

More specifically, thicknesses at a value that is selected from a range with a lower limit of 1 micron and an upper limit of 20 microns, at a value that is selected from a range with a lower limit of 2 microns and an upper limit of 10 microns.

The nitriding and/or oxidation of surface areas of the areas near to the surface of the substrate, and the diffusion zone and link layer will be carried out up to a certain coating thickness, starting from the surface of the beam, which is selected from a range with a lower limit of 3 microns and an upper limit of 50 microns.

In particular, this coating thickness, in which the content of nitrate and/or oxygen of the beam is increased, from a range with a lower limit of 5 microns and an upper limit of 40 microns, preferably selected from a range with a lower limit of 10 microns and an upper limit of 30 microns.

To increase electrical conductivity and to improve adhesion, doped or not doped of the silicon or germanium based layer on the substrate, it is possible that the coating has at least one metallic element to be doped. For example, the metallic element is a soft metal, such as tin or indium, so as to reduce friction. Other elements, for example may be titanium, chromium, iron, aluminium, nickel, cobalt, molybdenum, gold, niobium, vanadium, platinum, palladium.

It is also possible that these, doped or not doped, silicon or germanium based coatings with at least one more doped non-metallic elements, such as fluorine or boron, be used to further reduce adhesion, for example where the surface energy is reduced even further.

It is particularly advantageous when nitriding for channelling and discharge into various pieces of equipment to be avoided, oxidation and separation of the coating in a single coating system to be carried out, particularly in a plasma system, so that the time-consuming intermediary steps be avoided. Particularly in relation to plasma systems, the advantage of the so-called simple up-scaling is made feasible, since these systems already have a very high dispersion capacity in the coating technique, and are thus sufficiently controlled. A procedural simplification is therefore achieved. Is it is a single piece of equipment that makes the plasma and gas nitrogen hardening possible.

As with the implementation of any procedures, when surface topography remains unchanged, it is advantageous to decrease friction and thus to improve tribology of the apparatus or device's working pieces. This is particularly the case if the outer surface coating proves to be almost spherical or conical. Especially advantageous for tribologically improved characteristics of the equipment, and therefore for their use in tribological groups of components is when the surface structure is made up of a sprout-pattern type, with at least partly covered spherical segment elevation. This may mean that the arithmetic mean or the maximum surface finish according to DIN EN ISO 4287 will remain the same and that only the surface structure—in comparison to the surface of the average—may be changed or even accentuated at the same time as the alteration of surface structure.

In view of these special surface structure,s particularly if they are sprout-patterned, it is worth noting that this also leads to an improvement in the pollution gradient that such coated devices can reach. However, in some ways, a so-called self-cleaning effect called a lotus effect occurs.

In addition, this type of surface structure is also advantageous in view of the fact that the silicon or germanium based coating acts as an adhesive layer or intermediate layer for additional coatings, DLC coatings in particular, on the substrate.

The coating can be immediately isolated so that no more coating bonding agents are required, and therefore the cost is lower, and a simplification of the procedures to be carried out is made possible.

The invention also relates to the use of the device as a so-called tribological component. This is particularly the case for applications with dynamic friction, so that the friction occurs when two parts move in relation to each other, and improved properties can be obtained.

As mentioned above, the discovery also relates to the use of the device as a substrate for additional coatings, whereby the coating layer acts as an adhesion enhancer.

Because of the interaction of the oxide layer on the substrate and the silicon or germanium based substance on the oxide coating, corrosion resistance can be improved, thus allowing the apparatus to contain corrosive elements.

Furthermore, the invention relates to the use of the device as a machine tool, whilst the corresponding properties of hardness and in turn the tribological properties of this device remain in the foreground.

Finally, the invention relates to the use of the device as a forming tool, in particular due to the reduced adhesive capacity.

For a better understanding of the invention, the following illustrated examples will be explained.

A simplified schematic representation is shown for each.

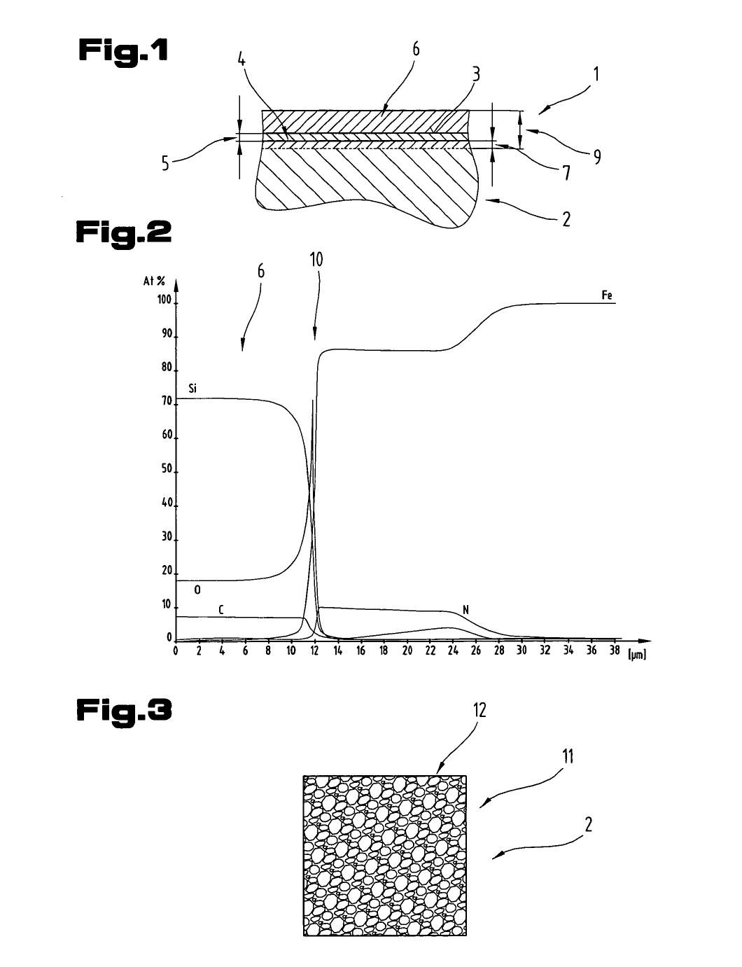

FIG. 1 A cross-section of the surface areas of an excerpt of the device

FIG. 2 GDEOS depth profile of a coated substrate

FIG. 3 A surface excerpt with sprout-patterned surface topography

First of all we must identify that there are differing descriptions of the embodiments for the same parts and with the same reference sign or identifier for the same component, while the description throughout contained for these same parts, has the same reference sign in essence, the component names can be transferred. Also, the descriptions on certain location information, such as up, down, sideways, etc. are shown directly on the diagram, they are based on a variable change, that are in turn transferred to the new variable. Furthermore, individual sets of properties or combinations of different properties can be seen through the various examples of implementation that are shown as independent, innovative and inventive modern solutions. It can be noted that in the following descriptions, not only silicon-based coatings are explored, several descriptions apply also to germanium and mixtures of silicon and germanium based strata.

FIG. 1 shows an excerpt from device 1 and shall include a metallic carrier 2, a surface 3. The surface 3 is formed from oxide 4, which consists of at least one part of the substrate material 2 and was formed by oxidizing treatment. Oxide 4 is to reach a thickness of up to 5 erected in surface area 3. On surface 3, coating 6 is deposited, possible resulting from doped, amorphous, silicon or silicon dioxide more specifically. Coating 6, has a particular diamond-like structure on which the silicon based coating possess a very high degree of hardness. This hardness in particular can have a value that is selected from a range with lower limit of HV 250 and upper limit of HR 5500, measured with a test load of 30 mN.

Below the layer of oxide 4 there is a thickness of up to 7—a layer with higher nitrate content in comparison to the remaining substrate 2. This coating is hereafter referred to as nitrate coating 8.

Nitrate layer 8 and oxide coating 4 combined with coating 6 produce coating 9.

The substrate is formed in this example by hardening and tempering or constructional steel. These materials are relatively soft, so the loads are correspondingly difficult to maintain. To increase the hardness, particularly the surface hardness, a state of the art invention, which has already been discussed is used, nitriding surface 3. For example, nitration can be carried out on plasma nitriding, for example and a nitrogen-hydrogen mixture is used, which leads to a plasma reaction, and binding of nitrogen occurs on the surface. The nitrogen diffuses due to high temperature of the steel during the treatment (about 450° C. to 600° C.) in the surface material under the formation of a wear resistant nitride coating. Hardness values of up to 1200 HV can thus be achieved. Thickness 7 and hardness can be chosen using appropriate parameters. In addition to increasing wear resistance, there is also a higher degree of corrosion resistance of substrate 2 that is achieved. Nitration of beam 2, i.e. the surface layer, can in principle be carried out with any suitable type, which consists of aforementioned invention. For example, nitration by gas or salt bath nitriding, is state of the art. As for the process gases, N2, NH3, N2H2, NH3N3, NH4N3 can be used, for example.

As for the plasma carbonitriding process, methane can be mixed with carbon dioxide or other carbon dispensers such as C2H2 can be used.

With nitriding, primarily Fe4N link layers or Fe2-3N arise.

It is preferable that the experiments remain within the framework of the investigation, however plasma activated chemical vapour deposition (PACVD technique) can also be applied. Likewise, the so-called PE-CVD technique (plasma enhanced chemical vapour deposition) is preferred, as it is already well-known and documented in, “S. Fujimaid, et al.; New DLC coating method using magnetron plasma in an unbalanced magnetic field; 59, 2000, 657-664 vacuum”, for example.

Instead of nitriding, it is also possible for substrate 2 of carbonitriding to be made.

The same applies to coating 6, which can be formed with silicon, for instance—notably amorphous silicon to produce substrate 2, which means that for device 1 products, if the required hardness is maintained, which lies within the realms of the study, it is also possible to develop a coating oxide 4 on the nitriding of substrate 2, for example, and in the same way to develop a coating oxide 4 from substrate 2.

For oxidation of the surface layer, water vapour is preferable. In the context of the investigation, it is also possible to use other oxygen input such as pure oxygen, ozone, or CO2.

By oxidation of the ferrous material, the primarily stages Fe3O4 are additional.

It should be noted that these stages are obviously limited to ferrous materials, and that there are other nitriding and oxidising stages for coating 2.

Oxidation may also be carried out alongside nitration, for example if NO, NO2, N2O, N2O4 or N2O5 as NO3 are used as process gases.

Coating 6 may, for example, be formed through pure silicon or pure silica. Similarly, both silicon and the silica, as mentioned above, must be doped. It is also possible that these silicon based coatings are amorphous or crystallised. In particular, it is advantageous in terms of wear resistance when coating 6 has similar characteristics to the carbon-based layers, that are known as DLC coatings. They can also be described as DLC-Si coatings. These layers are described in the literature that is quoted above.

As for the substrate 2—aluminium, chromium, molybdenum, gold, indium, niobium, manganese, titanium, platinum, palladium and tellurium used, alloys of these metals can also be considered.

It is preferable that processes remain within the framework of the investigation for nitriding as well as for oxidation and evaporation of coating 6 and should only be carried out in plasma conditions. Such plasma systems are already well-known and are adequately described in the literature that has been given. The process is so well known in the literature we have given, and reference should be given to Ruth Chatterjee-Fischer et al., Heat treatment of ferrous materials, Nitriding and Nitrocarburizing, 2 Circulation, 1995. Plasma treatment is usually carried out using a recipient, that will be adequately equipped with gas and suction, and the corresponding improvements such as the electrodes, and gas links, etc. will be made available.

As regards to the procedure itself, it is possible that for nitriding and/or the manufacture of the coating 6, appropriate DC or preferably pulsed DC or AC voltage should be carried out.

FIG. 2 shows a GDOES depth profile of surface areas of substrate 2 on FIG. 1. Thickness in microns is indicated on the ranges of concentration of each element in Atom Percentage. It is easy to see that the thickness of coating 6, according to FIG. 1, is approximately 12 microns, and manufactured from carbon-doped silicon dioxide. In transition zone 10, the oxygen peak where oxide 4 is in accordance with FIG. 1 is indicated. On the right-hand side, iron content prevails, with up to a thickness of approx. 25 microns, coating also contains nitrogen and carbon.

Although the diagram is to be understood schematically, taking into account that single curves are to be understood as an exception, the corresponding errors that can be perceived through the diagram representation emerge with this explanation of the findings. This is to say that in other words, the given concentration values, and those taken from the diagram, only depict reality to a certain degree of accuracy.

As for the manufacturing of the same coating, the following procedural parameters—for dependence and for size of equipment—will be used.

Pressure: 10 Pa to 1000 Pa

Voltage: 300 V to 1500 V

Hexamethyldisiloxan (HMDSO), Tetramethylsilan (TMS), Si-/Ti-Precourser: 0.1 l/h to 100 l/h

H₂: 0 l/h to 400 l/h

O₂: 0 l/h to 400 l/h

N₂: 0 l/h to 400 l/h

Ar: 0 l/h to 100 l/h

C₂H₂: 0 l/h to 100 l/h

CH₄: 0 l/h to 100 l/h

Separator temperature: 600° C.-20° C.

Negative/positive pulse durations: 0.1 μs to 2000 μs

Interval durations: 0 μs to 2000 μs

Coating system 9, in particular, will be manufactured following FIG. 1 and FIG. 2 with the following parameters:

Pressure: 100 Pa

Voltage: 1000 V

Hexamethyldisiloxan (HMDSO), Tetramethylsilan (TMS), Si-/Ti-Precourser: 10 l/h

H₂: 50 l/h

O₂: 20 l/h

N₂: 100 l/h

Ar: 100 l/h

C₂H₂: 10 l/h

CH₄: 10 l/h

Separator temperature: 450° C.-150° C.

Positive pulse durations: 150 μs

Interval durations: 200 μs

As a hydrocarbon source, CH₄ as well as C₂H₂ and C₂H₆, C₃H₈, C₄H₁₀, etc. can be drawn upon.

As well as Argon hydrogen, Helium or Neon can be used as a thinning gas.

As has already been mentioned above, it is preferable that oxidation is followed by steaming.

At this point it should be noted that it will be indicated as to whether the above-mentioned doping elements are non-metallic or metallic, to avoid unnecessary repetition. The purpose of this is to ensure that each one is referenced.

Manufacturing of the coating systems is preferred to be carried out throughout the separation of the gas stage.

Finally, FIG. 3 shows a schematic SEM micrograph of a surface cutaway 11 of the substrate as per FIG. 1. The sprout-pattern surface topography 12 is highly apparent. This surface topography 12 is particularly favoured with respect to tribological applications of the equipment 1.

As previously mentioned, it is possible to select the coating 6 by way of suitable process management, e.g. through the variation of voltage and/or temperature and/or pressure of the surface structure, such that not only does this preferred sprout-pattern surface topography 12 develop but the original surface finish of the nitrogen-hardened and/or oxidised surface of the substrate 2 is also reproduced. It is also possible, by appropriately selecting the process parameters, to attain the smoothest possible surface.

In preferable terms, high precipitation temperatures are not selected if amorphised coatings are to be produced.

The coating system 9, as per the invention, can be used in a range of applications as stated above. For example, this system is applicable in the weapons industry, in the piston sector, in hydraulic/pneumatic cylinder production, in mould and die construction, in particular in the plastics industry and for the production of aluminium parts, in chip removal and in wood processing. For example, gas-filled shock absorbers, automotive shock absorbers for cars and HGVs, hydraulic cylinders, e.g. for construction machinery, hydraulic blocks, pneumatic cylinders, parts for the engine and gearbox sector such as cam shafts, cam followers, bucket tappets, cylinder liners, piston rings, synchroniser rings, gearshift lever shafts, coupling flanges (in particular pressure plates), gear shift linkages, gear sticks and thrust washers or in automotive manufacturing in general, for example for brake pistons, motorbike forks, agricultural vehicles, gear parts, wheel hubs, ball-type couplings (in particular wheel suspensions), in the tool production sector for drills, for example screw taps, mandrels, threading dies, tool holders, in general machine building for liner guides, ball systems, guide bolts, robot grippers, and for weapon parts in general as well as parts used in shipbuilding. The advantages of coating system 9 lie not only in an improvement in the mechanical characteristics as well as certain other physical attributes such as the temperature resistance of the equipment 1, but also in the fact that (as already mentioned in introductory terms) a special optical effect is achieved with coating system 9, in particular a deep black colour, which negates any requirement for the further processing of these surfaces in order to attain the requisite appearance.

All value range specifications in the objective description should be taken as arbitrary ranges which encompass all subareas lying within these ranges, e.g. the specification 1 to 10 should be understood to encompass the full range starting from the bottom limit 1 and rising to the top limit 10, i.e. all subareas start with a bottom limit of 1 or more and end with a top limit of 10 or less, e.g. 1 to 1.7, or 3.2 to 8.1, or 5.5 to 10.

The configuration examples show or describe possible configuration variants for equipment 1 or the process as per the invention, whereby it is noted at this point that the invention is not restricted exclusively to the configuration examples specifically described, but instead facilitates diverse consolidated combinations of the individual configuration variants, and that the possibilities of variation depend, due to the technical teaching protected by patent, on the ability of the professional in this technical area. All conceivable configuration variants that are possible through the combination of individual details of the presented and described configuration variants are thus also protected by the scope of the patent.

As a matter of form, it is finally also noted that in order to facilitate enhanced understanding, the presentation of equipment 1 has been simplified, and is in part not to scale and/or enlarged and/or reduced in size.

The fundamental function of the independent innovative solutions can be taken from the description.

Primarily, the individual configurations shown in FIGS. 1; 2; 3 can be used to establish the object of independent solutions as per the invention. In this regard, the functions and solutions as per the invention can be taken from the detailed descriptions pertaining to these figures.

### REFERENCE SIGN ITEMISATION

1 Equipment

2 Substrate

3 Surface

4 Oxide

5 Layer thickness

6 Coating

7 Layer thickness

8 Nitric layer

9 Coating system

10 Transition zone

11 Surface cutaway

12 Surface topography

1. Process for the production of a coating (6) on the basis of at least one material selected from a group comprising silicon, germanium, and the oxides SiOₓ or GeOₓ of these elements, whereby these are doped where applicable and produced specifically amorphized, on at least a subsection of a surface (3) of a metallic substrate (2), whereby the concentration of nitrate is increased in the substrate (2) where applicable prior to precipitation of the coating (6) at least in the area of the subsection, wherein this subsection is subjected to oxidation prior to precipitation of the coating (6).

2. Process as per claim 1, wherein the oxidation is carried out after the nitrogen-hardening.

3. Process as per claim 1, wherein the increase in the nitrate content is achieved by plasma nitration or plasma nitrocarburization.

4. Process as per claim 1, wherein the oxidation is carried out with steam.

5. Process as per claim 1, wherein the coating (6) is carbon and/or nitrogen-doped for at least part of the coating thickness.

6. Process as per claim 5, wherein a concentration gradient of carbon and/or nitrogen is regulated in the coating (6).

7. Process as per claim 1, wherein a pulsed discharge is used for the precipitation of the coating (6).

8. Process as per claim 1, wherein the coating (6) is deposited on the substrate with a layer thickness (5) that is selected from a range with a bottom limit of 1 μm and a top limit of 25 μm.

9. Process as per claim 1, wherein the nitrogen-hardening and/or oxidation is carried out to a layer thickness (7) of the substrate (2) that is selected from a range with a bottom limit of 3 μm and a top limit of 50 μm.

10. Process as per claim 1, wherein the coating (6) is doped with at least one metallic element.

11. Process as per claim 1, wherein the coating (6) is doped with at least one additional non-metallic element.

12. Process as per claim 1, wherein the nitrogen-hardening, the oxidation and the precipitation of the coating (6) on the surface (3) of the substrate (2) is carried out in a single system.

13. Equipment (1), producible within the framework of a process as per claim 1, comprising a metallic substrate (2), upon at least a subarea of the surface (3) of which is a coating (6) on the basis of at least one of the materials from a group comprising silicon, germanium, and the oxides SiOₓ and GeOₓ of these elements, whereby these are doped where applicable and produced specifically amorphized, whereby at least a subarea of the substrate (2) close to the surface (3) has been nitrogen-hardened, wherein the substrate (2) at least in a subarea close to the surface (3) is pre-treated by way of oxidation.

14. Equipment (1) as per claim 13, wherein the concentration of nitrogen in the area close to the surface is selected from a range with a bottom limit of 1 atomic % and a top limit of 30 atomic %.

15. Equipment (1) as per claim 13, wherein the concentration of oxygen in the area close to the surface is selected from a range with a bottom limit of 1 atomic % and a top limit of 30 atomic %.

16. Equipment (1) as per claim 13, wherein the coating (6) is doped with carbon and/or nitrogen.

17. Equipment (1) as per claim 16, wherein the concentration of carbon in the coating (6) is selected from a range with a bottom limit of 1 atomic % and a top limit of 100 atomic %

18. Equipment (1) as per claim 16, wherein the concentration of nitrogen in the coating (6) is selected from a range with a bottom limit of 1 atomic % and a top limit of 60 atomic %.

19. Equipment (1) as per claim 13, wherein the coating (6) is doped with at least one metallic element.

20. Equipment (1) as per claim 13, wherein the coating (6) is doped with at least one additional non-metallic element.

21. Equipment (1) as per claim 13, wherein the doping element in the coating (6) exhibits a total concentration that is selected from a range with a bottom limit of 5 atomic % and a top limit of 60 atomic %.

22. Equipment (1) as per claim 13, wherein one of the surfaces of the substrate (2) has a coating (6) applied to it with an elevated surface topography (12), whereby the elevation is almost spherical segment/spherical in form.

23. Equipment (1) as per claim 22, wherein the surface topography (12) is at least roughly sprout patterned.

24. Equipment (1) as per claim 13, wherein the coating (6) is applied to the substrate directly.

25. Use of equipment (1) as per claim 13, as a tribologically loaded design element.

26. Use of equipment (1) as per claim 13 as a substrate for further coatings.

27. Use of equipment (1) as per claim 13 in corrosive media.

28. Use of equipment (1) as per claim 13 as a chipping tool.

29. Use of equipment (1) as per claim 13 as a moulding tool.
